(19) United States
(12) Patent Application Publication
(10) Pub. No.: US 2022/0262811 A1
(43) Pub. Date: Aug. 18, 2022

(54) SEMICONDUCTOR STORAGE DEVICE

(71) Applicant: Kioxia Corporation, Tokyo (JP)

(72) Inventors: Hiromitsu Iino, Nagoya Aichi (JP); Shunpei Takeshita, Yokkaichi Mie (JP); Naoki Yamamoto, Kuwana Mie (JP); Kazuhiro Nojima, Mie Mie (JP)

(21) Appl. No.: 17/395,220

(22) Filed: Aug. 5, 2021

(30) Foreign Application Priority Data
Feb. 18, 2021 (JP) 2021-024335

(51) Int. Cl. H01L 27/11556; H01L 27/11582; H01L 27/11519; H01L 27/11565; H01L 27/1157; H01L 27/11524; G11C 16/04

(52) U.S. Cl. CPC H01L 27/11556; H01L 27/11582; H01L 27/11519; G11C 16/0483; H01L 27/1157; H01L 27/11524; H01L 27/11565

(57) ABSTRACT

According to one embodiment, a semiconductor storage device includes a stacked section in which a plurality of conductor layers are stacked along a first direction and a stepped section in which the plurality of conductor layers are in a stepped shape. The stepped section includes a lower stepped section and an upper stepped section. In the upper stepped section, the conductor layers closer to the lower stepped section side along the first direction extend longer toward one side along a second direction orthogonal to the first direction. The lower stepped section is located at a position toward an opposite side to the one side along the second direction with respect to the upper stepped section.

### CROSS-REFERENCE TO RELATED APPLICATION

This application is based upon and claims the benefit of priority from Japanese Patent Application No. 2021-024335, filed Feb. 18, 2021, the entire contents of which are incorporated herein by reference.

### FIELD

Embodiments described herein relate generally to a semiconductor storage device.

### BACKGROUND

In a semiconductor storage device such as, for example, a NAND flash memory, a plurality of conductor layers are stacked on a substrate, and a memory pillar is formed so as to penetrate the conductor layers. The intersection of each conductor layer and the memory pillar functions as a memory cell for storing data. The conductor layers can be used as a word line for applying a voltage to a gate electrode of a memory cell.

It is generally necessary to connect a contact extending in a direction perpendicular to the surface of the substrate to each of the conductor layers. Therefore, the conductor layers typically have a stepped shape away from a portion in which the memory pillars are formed to permit connection of the necessary contacts.

In order to increase the storage capacity of a semiconductor storage device, it is generally desirable to increase the number of stacked conductor layers. However, as the number of stacked conductor layers increases, it becomes more difficult to form holes (memory holes) for the formation of memory pillars in a single processing step. Accordingly, in recent years, it has become common to perform the stacking of conductor layers and the formation of memory holes penetrating the conductor layers in a plurality of times in a stepwise manner. During the manufacture of such a semiconductor storage device, the stepped section, which is a portion where the conductor layers are formed in a stepped shape for lead out, is often formed a plurality of times.

### BRIEF DESCRIPTION OF THE DRAWINGS

FIG. 1 is a diagram illustrating an equivalent circuit of a semiconductor storage device according to a first embodiment.

FIG. 2 depicts aspects of a semiconductor storage device according to a first embodiment.

FIG. 3 depicts aspects of a semiconductor storage device according to a first embodiment.

FIG. 4 depicts aspects of a semiconductor storage device according to a first embodiment

FIG. 5 to FIG. 16 depict aspects related to a method of manufacturing a semiconductor storage device according to a first embodiment.

FIGS. 17A and 17B are diagrams illustrating a configuration of a support column and the vicinity thereof.

FIG. 18 is a diagram illustrating a configuration of a support column and the vicinity thereof.

FIG. 19 is a diagram illustrating a semiconductor storage device according to a comparative example.

FIGS. 20A to 20D depict aspects related to a method of manufacturing a semiconductor storage device according to a second embodiment.

FIG. 21 depict aspects related to a method of manufacturing a semiconductor storage device according to a second embodiment.

FIG. 22 depicts aspects of a semiconductor storage device according to a third embodiment.

FIG. 23 depicts aspects of a semiconductor storage device according to a fourth embodiment.

FIG. 24 depicts aspects of a semiconductor storage device according to a fifth embodiment.

FIG. 25 depicts aspects of a semiconductor storage device according to a sixth embodiment.

FIG. 26 depicts aspects of a semiconductor storage device according to a sixth embodiment.

### DETAILED DESCRIPTION

Embodiments provide a semiconductor storage device in which a stepped section can be more easily formed.

In general, according to one embodiment, a semiconductor storage device includes a plurality of conductor layers stacked along a first direction. The plurality of conductor layers comprises a first stacked section and a stepped section next to the first stacked section in a second direction orthogonal to the first direction. The plurality of conductor layers in the stepped section have a stepped shape in which the conductor layers arranged in the first direction have end portions that do not overlap in the first direction. The stepped section has a lower stepped section and an upper stepped section. The upper stepped section is located at a position different from the lower stepped section along the first direction. In the upper stepped section, the conductor layers closer to the lower stepped section side along the first direction extend longer toward one side along the second direction. The lower stepped section is located at a position toward an opposite side to the one side along the second direction with respect to the upper stepped section.

Hereinafter, the certain example embodiment will be described with reference to the accompanying drawings. In order to facilitate understanding of the examples, the same components in different examples and/or drawings will be designated with the same reference numerals, and the duplicate descriptions thereof will be omitted.

### First Embodiment

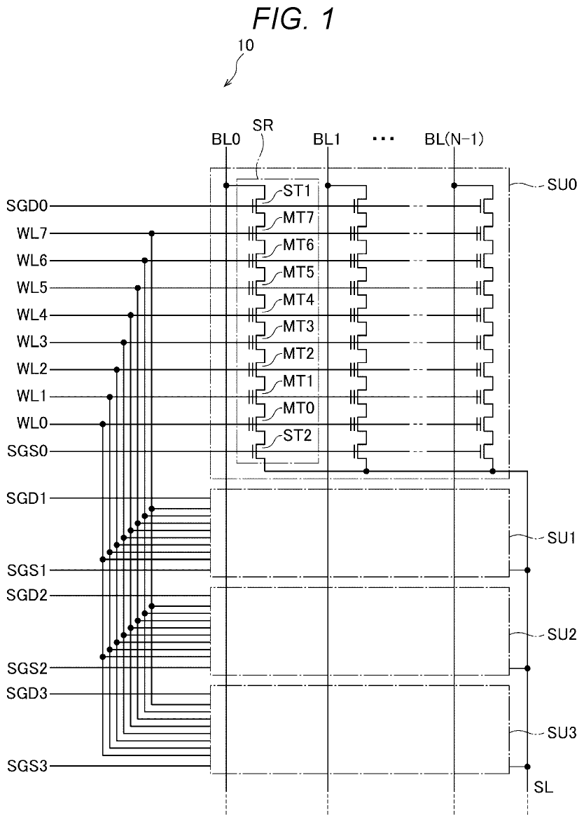

A semiconductor storage device 10 according to the present embodiment is a non-volatile storage device configured as, for example, a NAND flash memory. FIG. 1 illustrates a configuration of the semiconductor storage device 10 as an equivalent circuit diagram. The semiconductor storage device 10 includes a plurality of string units SU0 to SU3. Each of the string units SU0 to SU3 includes a plurality of NAND strings SR. Further, each NAND string SR includes, for example, eight memory cells MT0 to MT7 and two select transistors ST1 and ST2.

In the following description, each of the string units SU0 to SU3 may be referred to as “string unit SU” without distinction. Similarly, each of the memory cells MT0 to MT7 may be referred to as “memory cell MT” without distinction and each of the select transistors ST1 and ST2 may be referred to as “select transistor ST” without distinction.

The plurality of string units SU0 to SU3 constitute one block as a whole, and a plurality of such blocks are provided in the semiconductor storage device 10. In FIG. 1, only a single block is illustrated, and the illustration of the other blocks is omitted. In addition, the number of string units SU included in one block is not limited to that illustrated in FIG. 1. Further, the number of memory cells and the number of select transistors included in the NAND string SR may also be different from the example of FIG. 1.

Each string unit SU includes the same number of NAND strings SR as N bit lines BL0 to BL(N−1) provided. Nis a positive integer. The memory cells MT0 to MT7 included in the NAND string SR are arranged in series between a source of the select transistor ST1 and a drain of the select transistor ST2. A drain of the select transistor ST1 is connected to any of bit lines BL0 and the like. A source of the select transistor ST2 is connected to a source line SL. In the following description, each of the bit lines BL0 to BL(N−1) may be referred to as “bit line BL” without distinction.

Each memory cell MT is configured as a transistor having a charge storage layer at a gate portion. The amount of charges stored in this charge storage layer corresponds to data held in the memory cell MT. The memory cell MT may be of a charge trap type using, for example, a silicon nitride film as the charge storage layer, or may be of a floating gate type using, for example, a silicon film as the charge storage layer.

Gates of a plurality of select transistors ST1 included in the string unit SU0 are all connected to a select gate line SGD0. The select gate line SGD0 is a line to which a voltage for switching the opening and closing of each select transistor ST1 is applied. Similarly, for the string units SU1 to SU3, select gate lines SGD1 to SGD3 for applying a voltage to the select transistor ST1 are provided to correspond to each string unit SU.

Gates of a plurality of select transistors ST2 included in the string unit SU0 are all connected to a select gate line SGS0. The select gate line SGS0 is a line to which a voltage for switching the opening and closing of each select transistor ST2 is applied. Similarly, for the string units SU1 to SU3, select gate lines SGS1 to SGS3 for applying a voltage to the select transistor ST2 are provided to correspond to each string unit SU. In addition, the select gate line SGS may be shared between the string units SU0 to SU3 constituting one block, and the gates of all of the select transistors ST2 included in the string units SU0 to SU3 may be connected to the shared select gate line SGS.

Gates of the memory cells MT0 to MT7 are connected to word lines WL0 to WL7, respectively. The word lines WL0 to WL7 are lines to which a voltage is applied for the purpose of switching the opening and closing of the memory cells MT0 to MT7 or changing the amount of charges stored in each charge storage layer of the memory cells MT0 to MT7. Each of the word lines WL0 to WL7 is shared between the string units SU0 to SU3 constituting one block.

Writing and reading of data in the semiconductor storage device 10 are collectively performed for each unit called “page” on a plurality of memory cells MT connected to some word lines WL in some string units SU. Meanwhile, erasing of data in the semiconductor storage device 10 is collectively performed on all of the memory cells MT included in the block. Various known methods may be adopted as specific methods for performing such writing, reading, and erasing of data, and the detailed description thereof will be omitted.

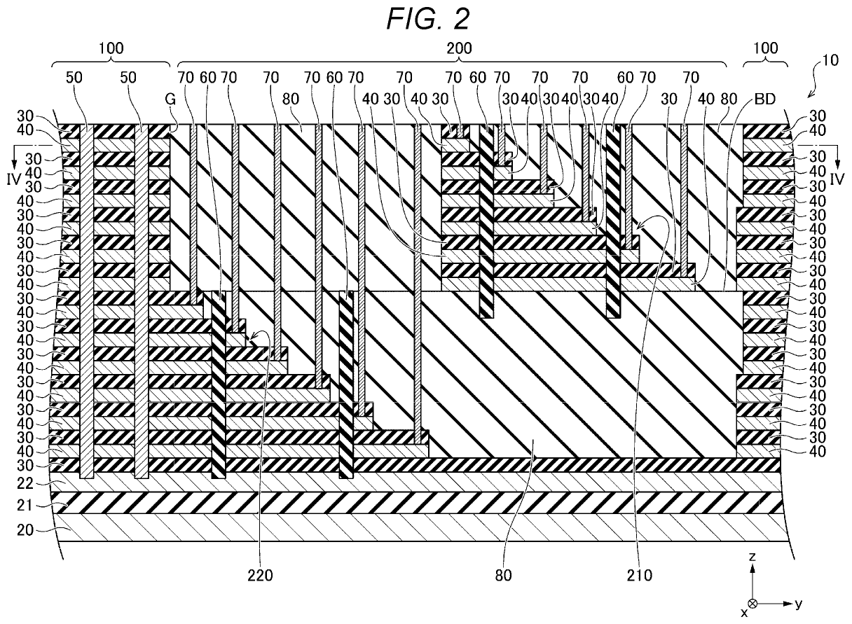

A specific configuration of the semiconductor storage device 10 represented by the equivalent circuit of FIG. 1 is illustrated in FIG. 2. As illustrated in FIG. 2, the semiconductor storage device 10 has a substrate 20, an insulator layer 21, a conductor layer 22, and a plurality of insulator layers 30 and conductor layers 40.

The substrate 20 is a plate-shaped member having a flat surface on the upper side of FIG. 2 and is, for example, a silicon wafer. The insulator layer 21, the conductor layer 22, the insulator layer 30, and the conductor layer 40 to be described below are a plurality of films layered on the upper surface side of the substrate 20 by, for example, CVD film formation.

In FIG. 2, the direction which is perpendicular to the surface of the substrate 20 and is directed from the lower side to the upper side in FIG. 2 is the z direction, and the z axis is set along that direction. Further, the direction which is perpendicular to the z direction and is directed from the left side to the right side in FIG. 2 is the y direction, and the y axis is set along that direction. Further, the direction which is perpendicular to both the z direction and the y direction and is directed from the paper front side to the paper back side of FIG. 2 is the x direction, and the x axis is set along that direction. In the following, the configuration of the semiconductor storage device 10 will be described while appropriately using each direction or each axis set in this way.

The insulator layer 21 is, for example, a layer formed of an insulating material such as silicon oxide. A peripheral circuit (not illustrated) for performing reading, writing, and erasing of data on the memory cell MT of FIG. 1 is formed on the surface of the substrate 20 on the z direction side. The insulator layer 21 covers the entire peripheral circuit, and prevents the peripheral circuit from conducting with the conductor layer 22.

The conductor layer 22 is a layer that functions as the source line SL. The conductor layer 22 is formed of, for example, a material containing silicon such as polycrystalline silicon or metal silicide doped with impurities, or a stacked structure of such a material containing silicon and a metal material. The conductor layer 22 is formed into a plate shape so as to cover the upper surface of the insulator layer 21 from the z direction side.

The plurality of insulator layers 30 and the plurality of conductor layers 40 are formed, respectively, and are formed so as to alternately cover a part of the conductor layer 22 from the z direction side. In addition, the number of stacked layers of the insulator layers 30 and the conductor layers 40 in FIG. 2 is different from the actual number of the stacked layers.

The conductor layers 40 are, for example, conductive layers formed of a material containing tungsten. In the conductor layer 40, the outer peripheral surface of the material containing tungsten may be covered with a barrier metal material such as titanium nitride. The conductor layers 40 are used respectively as the word lines WL0 to WL7 and the select gate lines SGS0 and SGD0 in FIG. 1. The insulator layer 30 is located at a position between the conductor layers 40 adjacent to each other, and serves to electrically insulate the two. The insulator layer 30 is formed of, for example, a material containing silicon oxide.

As illustrated in FIG. 2, in a region where the plurality of insulator layers 30 and conductor layers 40 are stacked along the z direction, a plurality of memory pillars 50 are formed so as to penetrate these layers along the z direction. Each memory pillar 50 is formed within a range from the insulator layer 30 on the most z direction side to the conductor layer 22. In addition, each memory pillar 50 corresponds to the NAND string SR illustrated in FIG. 1. The number of memory pillars 50 in FIG. 2 is different from the actual number.

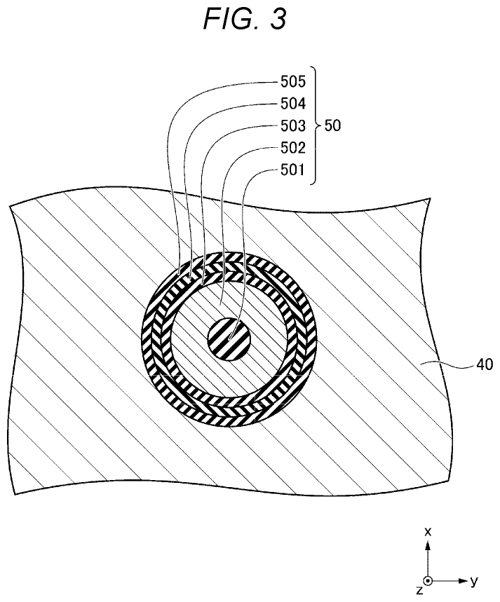

FIG. 3 schematically illustrates a cross section when one memory pillar 50 is cut along a plane perpendicular to the z axis. As illustrated in FIG. 3, each memory pillar 50 has a semiconductor 502, a tunnel insulating film 503, a charge storage film 504, and a block insulating film 505.

The semiconductor 502 has a tubular shape extending along the z direction within a portion where the plurality of insulator layers 30 and conductor layers 40 are stacked and is formed of, for example, a silicon material such as amorphous silicon or polysilicon. A core 501 formed of an insulating material is formed inside the tubular semiconductor 502. Instead of such a mode, there may be a mode in which the core 501 is not formed inside the semiconductor 502.

The tunnel insulating film 503 is a film that covers the outer peripheral surface of the semiconductor 502. The tunnel insulating film 503 is formed of, for example, a material containing silicon oxide. The charge storage film 504 is a film that covers the outer peripheral surface of the tunnel insulating film 503. The charge storage film 504 is formed of, for example, a material containing silicon nitride. The block insulating film 505 is a film that covers the outer peripheral surface of the charge storage film 504. The block insulating film 505 is formed of, for example, a material containing silicon oxide or a metal oxide having a permittivity higher than that of silicon oxide. The outer peripheral surface of the block insulating film 505 formed on the outermost side is surrounded by each of the stacked conductor layers 40.

In this way, transistors are formed, respectively, in portions where the memory pillar 50 and the plurality of conductor layers 40 face each other via the block insulating film 505, the charge storage film 504, and the tunnel insulating film 503. That is, a plurality of transistors are connected in series along the longitudinal direction of each memory pillar 50. Each conductor layer 40 functions as a gate for each transistor. The semiconductor 502 inside the conductor layer 40 functions as a channel for this transistor.

The respective transistors arranged next to each other in series as described above along the longitudinal direction of the memory pillar 50 have a portion functioning as the plurality of memory cells MT in FIG. 1. Further, the transistors formed at both ends of the plurality of memory cells MT arranged next to each other in series function as the select transistors ST1 and ST2 in FIG. 1.

In the end of the memory pillar 50 on the −z direction side, the block insulating film 505 and the like is removed, and the semiconductor 502 inside thereof is connected to the conductor layer 22. Thus, the conductor layer 22 functioning as the source line SL and the channel of each transistor are electrically connected to each other. Meanwhile, in the end of the memory pillar 50 on the z direction side, the semiconductor 502 is connected to the bit line BL in FIG. 1 via a contact (not illustrated).

In addition, various modes that are already known may be adopted as a configuration of the peripheral circuit or a specific operation thereof for realizing reading and writing of data on each memory cell MT. Therefore, the further specific description will be omitted.

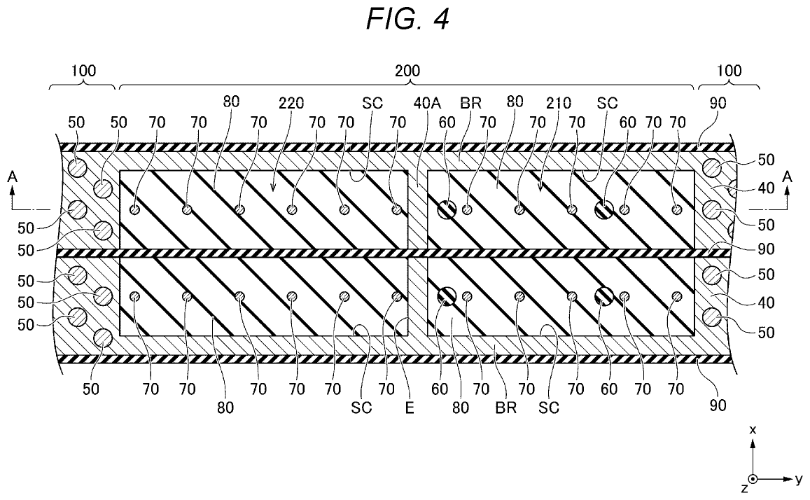

In FIG. 2, the reference numeral “100” is given to a portion where the plurality of conductor layers 40 are stacked respectively in substantially the same plate shape so as to cover the substrate 20 and the plurality of memory pillars 50 are formed so as to penetrate the plurality of conductor layers 40. This portion is hereinafter also referred to as “stacked section 100.” The stacked section 100 can also be said to be a portion where the plurality of memory cells MT are formed to store data. In FIG. 2, two stacked sections 100 spaced from each other along the y direction are depicted. As illustrated later in FIG. 4, the plurality of memory pillars 50 are also formed in the stacked section 100 on the y direction side so as to penetrate the plurality of conductor layers 40.

As illustrated in FIG. 2, in a portion between the two stacked sections 100, the respective insulator layers 30 and the respective conductor layers 40 are formed into a stepped shape. In this region, since each conductor layer 40 is formed into a stepped shape, a portion (terrace portion) of each conductor layer 40 is in a state of being exposed to the z direction side without being blocked by another conductor layer 40. The end of a contact 70 extending in the z direction is connected to each conductor layer 40 exposed in this way. The contact 70 is, for example, a columnar member formed of a conductive material such as tungsten.

Each of the conductor layers 40 formed into a stepped shape is electrically connected to a respective one of the conductor layers 40 stacked in the stacked section 100 which is located at the same height position (z coordinate). With such a configuration, it is possible to individually perform the application of a voltage to the respective conductor layers 40 used as the word lines WL0 to WL7 and the select gate lines SGS0 and SGD0 via each contact 70. In order to enable the application of a voltage to the respective conductor layers 40 of the stacked section 100, the portion where the conductor layers 40 are formed into a stepped shape as described above is hereinafter also referred to as “stepped section 200.” The periphery of the stepped section 200 or the contact 70 is filled with an insulator 80. The insulator 80 is, for example, silicon oxide.

The number of conductor layers 40 actually stacked in the stacked section 100 is larger than the number illustrated in FIG. 2. The memory pillar 50 of FIG. 2 is formed so as to penetrate the whole of the conductor layers 40 in this way, and has an extremely elongate actual shape. In order to form the memory pillar 50 with high accuracy, the stacking of the insulator layers 30 and the formation of a hole for the memory pillar 50 are often divided into a plurality of times rather than being performed once. In the present embodiment, the stacking of the insulator layers 30 and the formation of the hole for the memory pillar 50 are performed by being divided into two times.

In FIG. 2, the reference character “BD” is given to a position serving as a boundary between a portion on the lower layer side which is formed in a first time and a portion on the upper layer side which is formed in a second time. This boundary is hereinafter also referred to as “boundary BD.” A portion of the stepped section 200 formed on the z direction side of the boundary BD is hereinafter also referred to as “upper stepped section 210.” Further, a portion of the stepped section 200 formed on the −z direction side of the boundary BD is hereinafter also referred to as “lower stepped section 220.”

The upper stepped section 210 is located at a position different from that of the lower stepped section 220, specifically, at a position on the upper side of the lower stepped section 220 along the z direction. In addition, the terms “lower” and “lower side” as used herein mean the −z direction side in the present embodiment at which the insulator layers 30 are formed first when the formation of the insulator layers 30 is divided into a plurality of times as described above. Meanwhile, the terms “upper” and “upper side” mean the z direction side in the present embodiment at which the insulator layers 30 are formed later when the formation of the insulator layers 30 is divided into a plurality of times as described above. Further, the “upper” and the “upper side” can also be said to be the direction side facing the surface (terrace surface) of the upper stepped section 210 or the lower stepped section 220 formed as a part of the conductor layer 40 is exposed without being blocked by another conductor layer 40.

The lower stepped section 220 is formed at a position of the stepped section 200 on the −y direction side. The upper stepped section 210 is formed at a position of the stepped section 200 on the y direction side of the lower stepped section 220.

FIG. 4 schematically depicts the configuration of the semiconductor storage device 10 in the IV-IV cross section of FIG. 2. In FIG. 4, the reference numeral “90” is given to a slit provided so as to divide the stacked section 100 and the stepped section 200. The slit is also hereinafter referred to as “slit 90.” In the slit 90, the insulator layer 30 and the conductor layer 40 constituting the stacked section 100 are divided along the x direction, and an insulating material serving as a spacer is provided therein on a sidewall portion of the slit 90 and at the same time, a conductive material (not illustrated) is embedded therein so as to be connected to the conductor layer 22. Instead of such a mode, there may be a mode in which the entire inside of the slit 90 is filled with an insulating material. The slit 90 serves to separate, for example, the string units SU or blocks adjacent to each other. A plurality of slits 90 are formed so as to be arranged next to each other along the x direction, but in FIG. 4, only three slits 90 are illustrated. In addition, the cross section illustrated in FIG. 2 corresponds to a cross section when the semiconductor storage device 10 is cut along A-A in FIG. 4.

In FIG. 4, the reference character “SC” is given to a rectangular opening formed in a portion of the conductor layer 40 corresponding to the stepped section 200. This opening is hereinafter also referred to as “opening SC.” In the cross section of FIG. 4, two openings SC are formed. A portion of the conductor layer 40 between the two openings SC (e.g., the portion designated by the reference numeral “40A” in FIG. 4) corresponds to the terrace portion of the conductor layer 40 located on the most +z direction side of the upper stepped section 210. In the portion of this conductor layer 40 designated by the reference numeral “40A,” an edge E which is the end on the −y direction side can be said to be a boundary between the lower stepped section 220 on the −y direction side and the upper stepped section 210 on the +y direction side.

As illustrated in FIG. 4, the conductor layer 40 is not completely divided by the opening SC. A gap is left between the opening SC and the slit 90, and conductor layer 40 extends along the y direction in this gap. The portion of the conductor layer 40 in the region/gap between the opening SC and the slit 90 is referred to as “bridge portion BR.” The bridge portion BR is provided for each of the plurality of stacked conductor layers 40.

In FIG. 4, the portion of the conductor layer 40 designated by the reference numeral “40A” can be connected via the bridge portion BR to a corresponding one of the conductor layers 40 in the stacked section 100 on the −y direction side and also the corresponding one of the conductor layer 40 of the stacked section 100 on the +y direction side. This applies to all of the other conductor layers 40 in the upper stepped section 210.

In this way, each conductor layer 40 in the upper stepped section 210 can be connected to a respective one of the conductor layers 40 at the same height position (z coordinate) in the stacked sections 100 at both sides along the y direction via the bridge portion BR. Therefore, a voltage applied from a contact 70 to a particular conductor layer 40 of the upper stepped section 210 will be applied to the corresponding conductor layer 40 (same height layer) of the stacked sections 100 on the −y direction side and the +y direction side.

As illustrated in FIG. 2, each conductor layer 40 of the lower stepped section 220 is directly connected to a respective one of the conductor layers 40 in the stacked section 100 on the −y direction side at the same height position (z coordinate). Furthermore, each conductor layer 40 of the lower stepped section 220 can be connected to the stacked section 100 on the +y direction side via a bridge portion BR similar to that illustrated in FIG. 4. Therefore, a voltage applied from a contact 70 of a particular conductor layer 40 in the lower stepped section 220 will be applied not only to the stacked section 100 on the −y direction side but also the stacked section 100 on the +y direction side.

As illustrated in FIG. 2, a plurality of support columns 60 extending along the z direction are formed in the stepped section 200. Each support column 60 penetrates at least a portion of the plurality of stacked conductor layers 40. The support column 60 is provided for the purpose of reinforcing the plurality of insulator layers 30 during replacement processing when the semiconductor storage device 10 is being manufactured. The support column 60 is formed of, for example, silicon oxide.

As described above, the semiconductor storage device 10 according to the first embodiment includes a stacked section 100 and a stepped section 200. The stacked section 100 is a portion where each conductor layers 40 overlaps every other conductor layer 40 in the z direction so as to cover the substrate 20. The z direction in which the respective conductor layers 40 are stacked corresponds to the “first direction” in the present embodiment.

The stepped section 200 is a portion of the stack that is arranged next to the stacked section 100 in the y direction. The stepped section 200 is a portion where the plurality of conductor layers 40 are formed in a stepped shape along the y direction. The y direction in which the stacked section 100 and the stepped section 200 are arranged next to each other is a direction perpendicular to the z direction (which is the first direction) and corresponds to the “second direction” in the present embodiment.

As already described above, the stepped section 200 includes the lower stepped section 220 and the upper stepped section 210. In the present embodiment, the lower stepped section 220 is located at a position toward the substrate 20 side along the z direction. The upper stepped section 210 is located at a position opposite to the substrate 20 side along the z direction with respect to the lower stepped section 220.

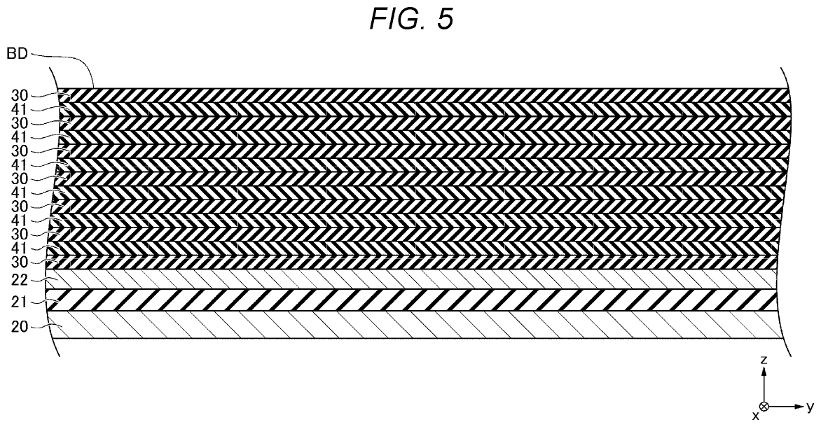

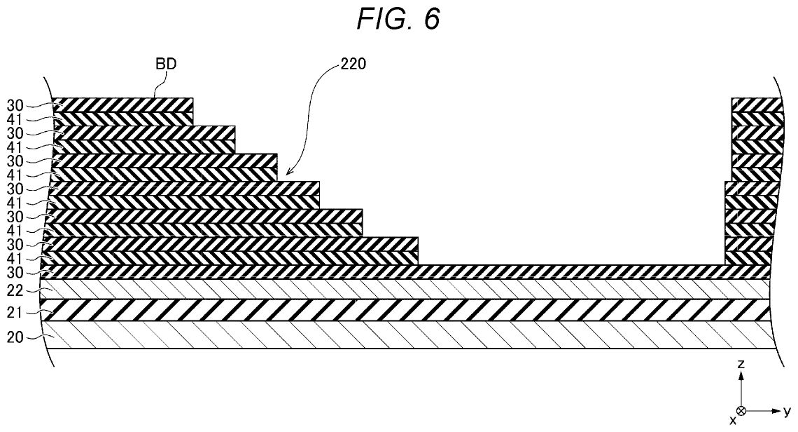

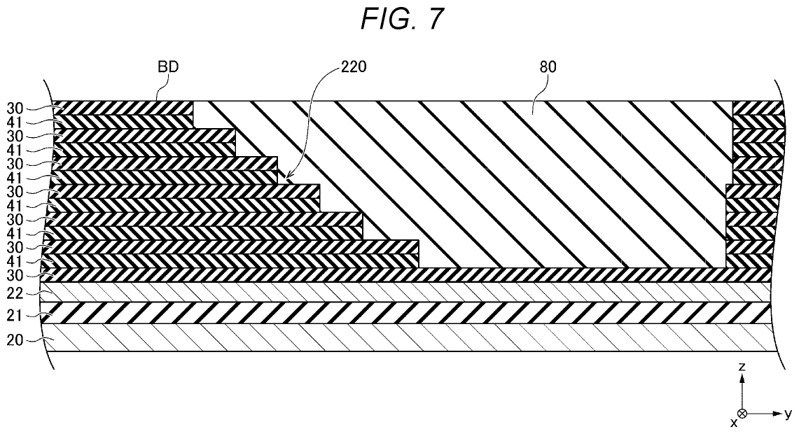

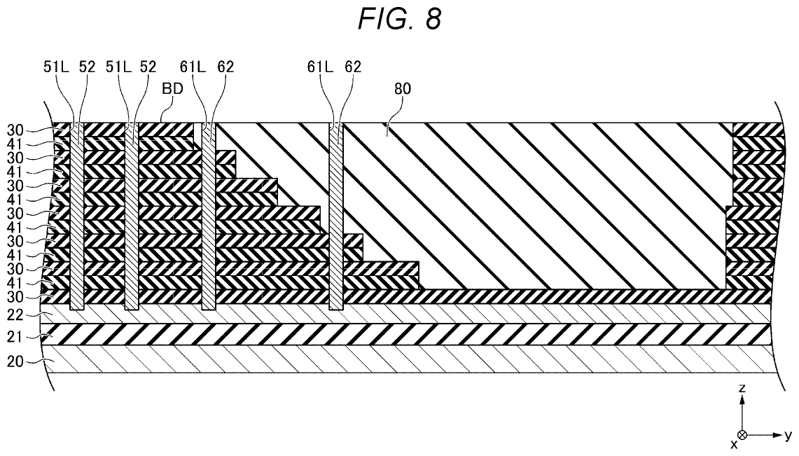

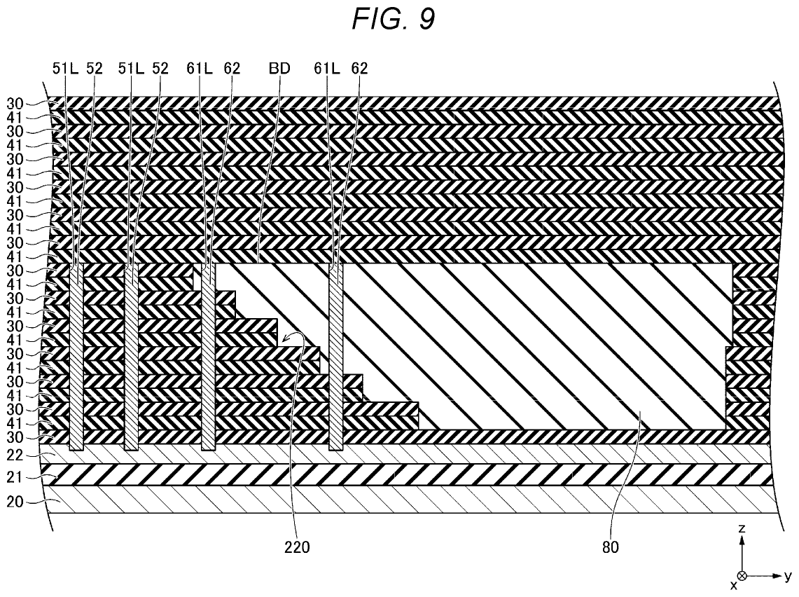

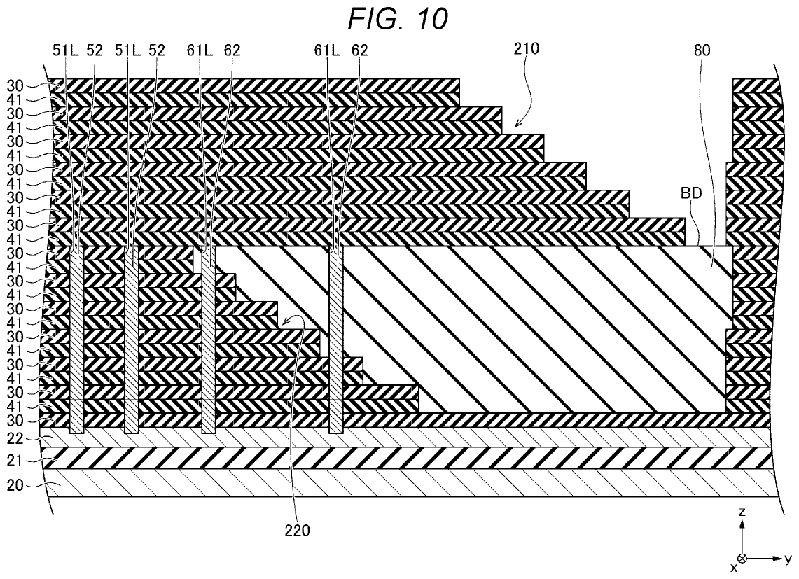

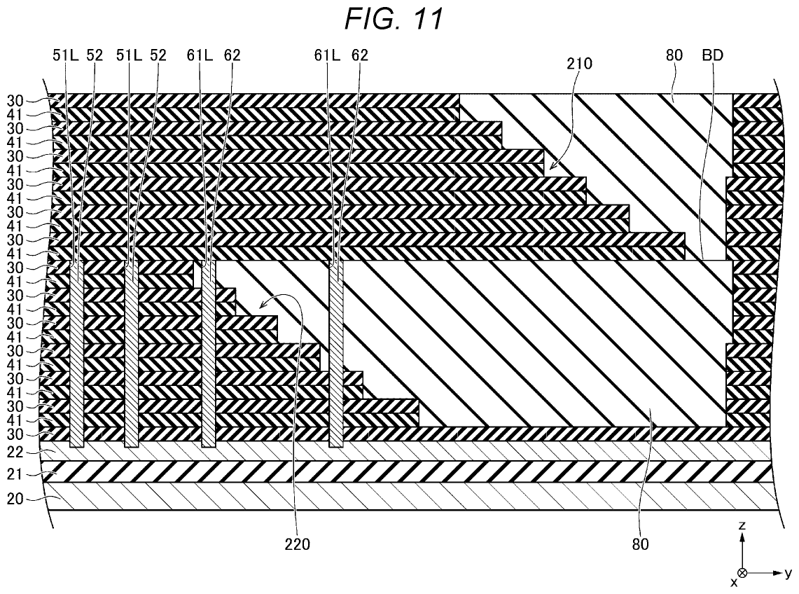

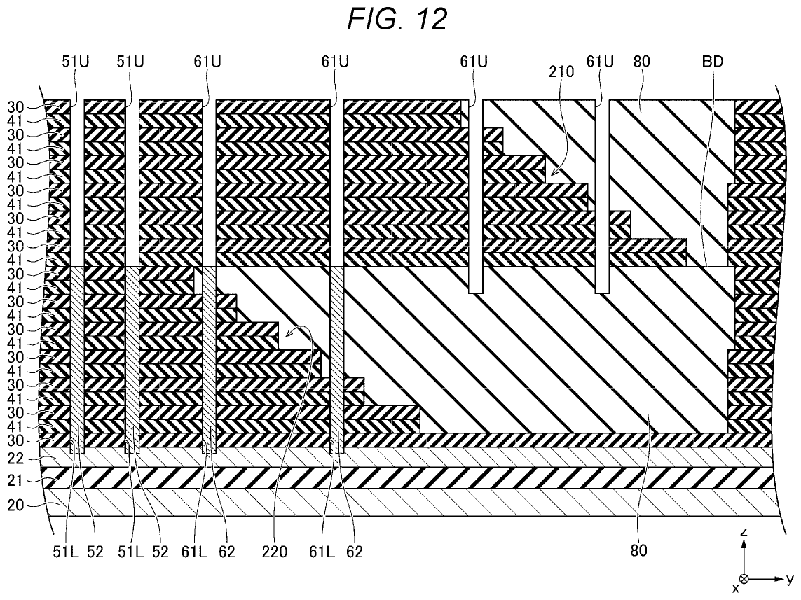

Next, a method of manufacturing the semiconductor storage device 10 will be described with reference to FIGS. 5 to 18.

<Lower Stacking Process> First, a lower stacking process is performed. In the lower stacking process, first, the insulator layer 21 and the conductor layer 22 are formed so as to cover the upper surface (+z direction side) of the substrate 20. The insulator layer 30 and a sacrificial layer 41 are alternately stacked so as to cover the upper surface of the conductor layer 22. The sacrificial layer 41 is a layer that is to be substituted (replaced) with the conductor layer 40 in a later process, and is, for example, formed of silicon nitride. The surface of the uppermost insulator layer 30 (the one formed on the most +z direction side) corresponds to the boundary BD in FIG. 2. FIG. 5 illustrates a state where the lower stacking process has been completed.

<Lower Step Forming Process> After the lower stacking process, a lower step forming process is performed. In the lower step forming process, for example, steps of anisotropic etching of a stack and lateral trimming of an etching mask are repeated to form the lower stepped section 220 in a part of the stacked insulator layers 30 and sacrificial layers 41. FIG. 6 illustrates a state immediately after the lower stepped section 220 is formed in this way. As illustrated in FIG. 6, the insulator layers 30 and the sacrificial layers 41 in a portion that is to be directly below the upper stepped section 210 are removed when the lower stepped section 220 is formed. After the lower stepped section 220 is formed, the periphery of the lower stepped section 220 (the void left by the removal of portions of the insulator layers 30 and sacrificial layers 41) is filled with the insulator 80.

<Lower Hole Forming Process> After the lower step forming process, a lower hole forming process is performed. In the lower hole forming process, a hole 51L is formed in a position corresponding to the memory pillars 50 and a hole 61L is formed in a position corresponding to the support columns 60. These holes are substantially cylindrical, and are formed by, for example, RIE. The holes 51L and the holes 61L reach the conductor layer 22. After that, the inside of the holes 51L are filled with a sacrificial material 52, and the inside of the holes 61L are filled with a sacrificial material 62. The same material can be used for the sacrificial material 52 and the sacrificial material 62. As such a material, for example, polysilicon or amorphous silicon may be used. FIG. 8 illustrates a state where the lower hole forming process has been completed and the holes have been filled.

<Upper Stacking Process> After the lower hole forming process, an upper stacking process is performed. In the upper stacking process, insulator layers 30 and sacrificial layers 41 are alternately stacked to cover the entire surface of the previously processed portion. Thus, now a portion on the +z direction side of the boundary BD is formed. FIG. 9 illustrates a state where the upper stacking process has been completed.

<Upper Step Forming Process> After the upper stacking process, an upper step forming process is performed. In the upper step forming process, for example, steps of anisotropic etching of a stack and lateral trimming of an etching mask are repeated to form the upper stepped section 210. FIG. 10 illustrates a state immediately after the upper stepped section 210 is formed in this way. The upper stepped section 210 is formed at a position near the +y direction side end of the lower stepped section 220. Therefore, the holes 61L formed in the lower stepped section 220 (and the sacrificial material 62 filling the inside of the holes 61L) remain covered by the stacked insulator layers 30 and the sacrificial layers 41 on the +z direction side even after the upper stepped section 210 is formed. After the upper stepped section 210 is formed, as illustrated in FIG. 11, the periphery of the upper stepped section 210 (void left by removal of portions of the stacked insulator layers 30 and the sacrificial layers 41) is filled with the insulator 80.

<Upper Hole Forming Process> After the upper step forming process, an upper hole forming process is performed. In the upper hole forming process, a hole 51U is formed in a position corresponding to the memory pillars 50 and a hole 61U is formed in a position corresponding to the support columns 60 along the boundary BD. FIG. 12 illustrates a state where the upper hole forming process has been completed.

As illustrated in FIG. 12, in a portion that is to be the stacked section 100 and a portion that is to be directly above the lower stepped section 220, the holes 51U and the holes 61U are respectively formed at positions directly above the holes 51L and the holes 61L (previously formed in the lower hole forming process). Therefore, the sacrificial material 52 in the holes 51L functions as a stopper (etch stop) when forming the holes 51U. Similarly, the sacrificial material 62 in the holes 61L functions as a stopper (etch stop) when forming the hole 61U.

However, since no hole 61L was formed at a position directly below the holes 61U that penetrate through the upper stepped section 210, thus, as illustrated in FIG. 12, these holes 61U extend beyond the boundary BD to −z direction side. However, since this region on −z direction side of the boundary BD is filled with the insulator 80, the holes 61U still do not penetrate any insulator layer 30 or sacrificial layer 41 on the −z direction side of the boundary BD.

<Sacrificial Material Removing Process> After the upper hole forming process, a sacrificial material removing process is performed. In the sacrificial material removing process, the sacrificial material 52 filling the holes 51L and the sacrificial material 62 filling the holes 61L are removed. When polysilicon or amorphous silicon is used as the sacrificial material 52/62, wet etching may be used.

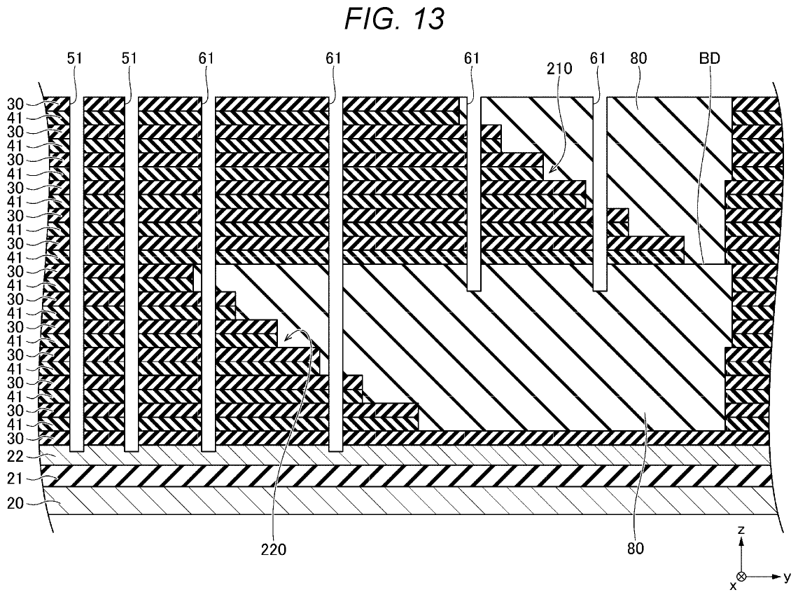

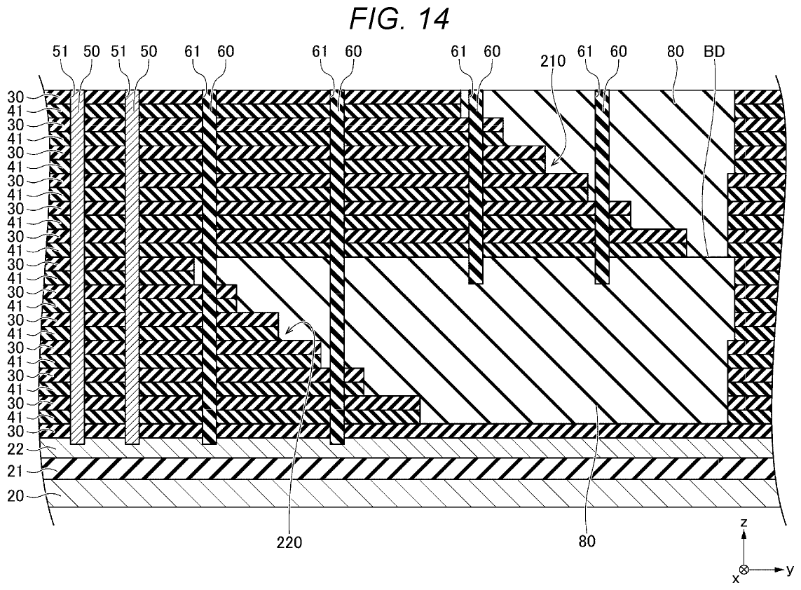

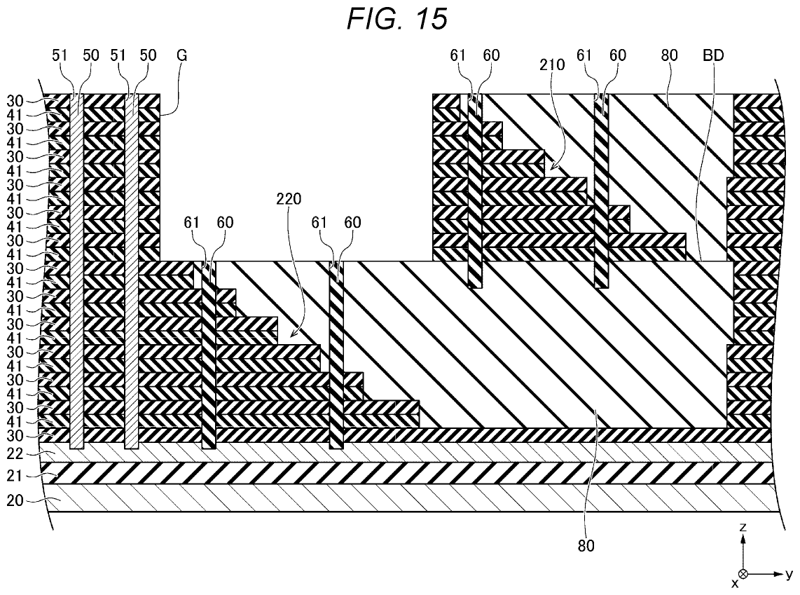

FIG. 13 illustrates a state where the sacrificial material removing process has been completed. When the sacrificial material removing process is completed, the hole 51L and the hole 51U arranged next to each other along the z axis are connected to each other, and these holes are now referred to as a hole 51. Similarly, the hole 61L and the hole 61U arranged next to each other along the z axis are connected to each other, and these holes are now referred to as a hole 61. The term “hole 61” is also used to refer those holes 61U formed so as to penetrate the upper stepped section 210.

<Memory Pillar and Others Forming Process> After the sacrificial material removing process, a memory pillar and support forming process is performed. In the memory pillar and support forming process, a memory pillar 50 is formed inside the holes 51 and a support column 60 is formed inside the holes 61. All of these are formed by, for example, CVD film formation. FIG. 14 illustrates a state where the memory pillar and support forming process has been completed.

<Opening forming Process> After the memory pillar and support forming process, an opening forming process is performed. In the opening forming process, a part of the insulator layers 30 and the sacrificial layers 41 stacked in the upper stacking process directly above the lower stepped section 220 is removed, whereby an opening G is formed. FIG. 15 illustrates a state where the opening forming process has been completed.

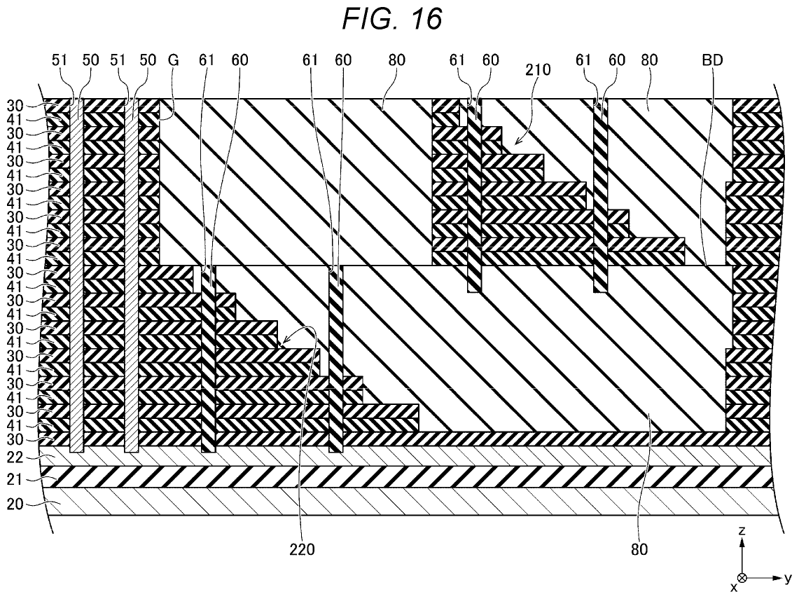

The opening G is formed so as to leave a portion of the sacrificial layer 41 that is to be the bridge portion BR (see FIG. 4). At the bottom of the opening G, that is, at the boundary BD, the upper end of the support column 60 provided in the lower stepped section 220 is exposed. After the opening G is formed, the inside of the opening G is filled with the insulator 80. as illustrated in FIG. 16.

<Replacement Process> After the opening forming process, a replacement process is performed. In the replacement process, first, the slit 90 (illustrated in FIG. 4) is formed. Thus, the stacked insulator layers 30 and sacrificial layers 41 are divided by the slit 90. After that, the sacrificial layers 41 are removed by wet etching via the slit 90. At this time, each of the stacked insulator layers 30 remains with a gap therebetween. However, since each insulator layer 30 is supported by the memory pillars 50 and the support columns 60, the shape thereof is maintained. After that, a conductor layer 40 is formed by, for example, CVD in each gap where the sacrificial layer 41 was previously present.

After the replacement process is completed, a conductive material can be embedded inside the slit 90 via an insulating material as a spacer coating the sidewalls of the slit 90. Further, after holes for the contacts 70 are formed in the surface of the insulator 80 by, for example, RIE, the contacts 70 are formed so as to fill these holes. Thus, the semiconductor storage device 10 illustrated in FIG. 2 is completed.

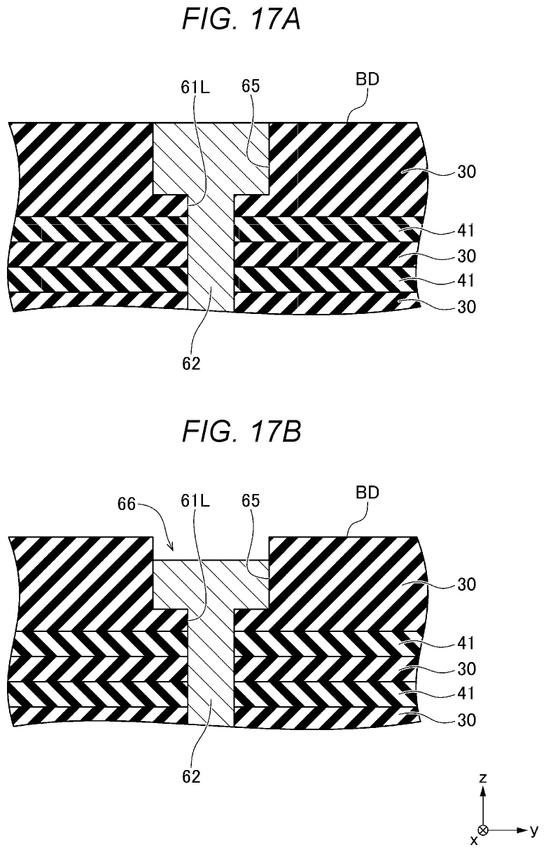

Hereinafter, the effect of arranging the upper stepped section 210 and the lower stepped section 220 as in the first embodiment will be described. FIG. 17A schematically depicts the state of a hole 61L and sacrificial material 62 immediately before the upper stacking process is performed. As illustrated in FIG. 17A, the inner diameter of the hole 61L is enlarged in the vicinity of the upper end of the hole 61L in the vicinity of the boundary BD. The portion enlarged in this way is referred to as “enlarged diameter portion 65.” With the formation of such an enlarged diameter portion 65, it is possible to more reliably connect the hole 61L and the hole 61U when forming the hole 61U in the upper hole forming process. Note, in FIG. 2 and the other figures used in the above description of the first embodiment, the illustration of the enlarged diameter portion 65 is omitted.

It is desirable to match the position of the upper end surface of the sacrificial material 62 inside the enlarged diameter portion 65 to the level of the boundary BD prior to the upper stacking process being performed. However, it can be difficult to completely match the two. In actuality, the upper end surface of the sacrificial material 62 is often located at a position lower than the boundary BD, as illustrated in FIG. 17B. As a result, a recess 66 is left at the position of the enlarged diameter portion 65.

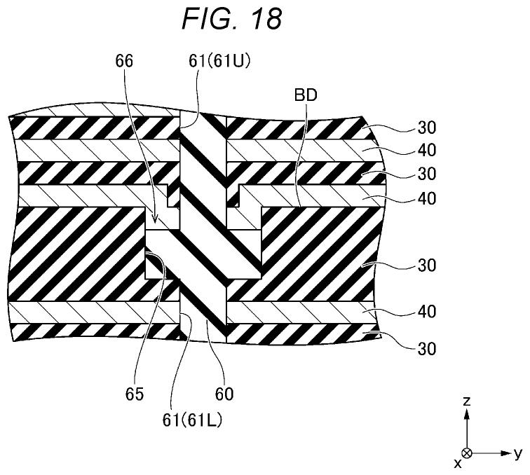

FIG. 18 schematically illustrates a state immediately after the replacement process has been performed when there was a recess 66 formed as illustrated in FIG. 17B. As illustrated in FIG. 18, in a portion directly above the enlarged diameter portion 65, the upper conductor layer 40 close to the boundary BD has a concave shape corresponding to the position of the recess 66.

However, in the replacement process, when a space in which the conductor layer 40 is to be formed has a concave shape, there is a possibility that the conductor layer 40 will not be formed so as to entirely fill the available space and a void may remain in a part of the space. Such a void is most likely to be generated at a position inside the recess 66 directly above the sacrificial material 62 filling the enlarged diameter portion 65.

Also, fluorine gas from the replacement process may remain inside the void. Therefore, in a later process, when the contact 70 is connected to the conductor layer 40 in the vicinity of the recess 66 that caused the generation of a void, an altered layer generated by the fluorine gas may cause a connection failure between the conductor layer 40 and the contact 70.

Accordingly, the first embodiment adopts a configuration in which a conductor layer 40 is not formed on the substrate 20 side of the upper stepped section 210. As illustrated in FIG. 2, in the first embodiment, the conductor layer 40 is not formed in a region below the upper stepped section 210. Thus, in this region, it is not necessary to form the support column 60 for reinforcing the insulator layer 30 at the time of replacement and as a result, even if the support column 60 penetrating the upper stepped section 210 exceeds the boundary BD and is terminated in the insulator 80 (on the −z direction side of the boundary BD), the enlarged diameter portion 65 and the recess 66 as illustrated in FIG. 17B will not be present in the portion beyond the boundary BD. Therefore, the connection failure with the contact 70 due to the void as described with reference to FIG. 18 does not occur in the conductor layer 40 of the upper stepped section 210 adjacent to the boundary BD.

Thus, with the configuration in which the upper stepped section 210 and the lower stepped section 220 are arranged in the above-mentioned positional relationship, it is possible to reliably prevent connection failures between a conductor layer 40 and a contact 70.

Another effect of adopting the configuration of the first embodiment will be described. A case in which carbon is used instead of polysilicon or amorphous silicon as the sacrificial materials 52 and 62 used in the lower hole forming process (FIG. 8) will be considered. For example, in the upper step forming process, there is a concern that both the stacked section 100 and the stepped section 200 may be warped due to heating, but this warpage may be reduced when carbon is used as the sacrificial materials 52 and 62.

Furthermore, after the upper hole forming process is completed as illustrated in FIG. 12, a mask used for forming the hole 61U may be removed by ashing. At this processing, the sacrificial materials 52 and 62, which are carbon in this example, would also be removed together with the mask by the ashing process. That is, when carbon is used as the sacrificial materials 52 and 62, there is a potential advantage in that a specific sacrificial material removing process as described above may be omitted.

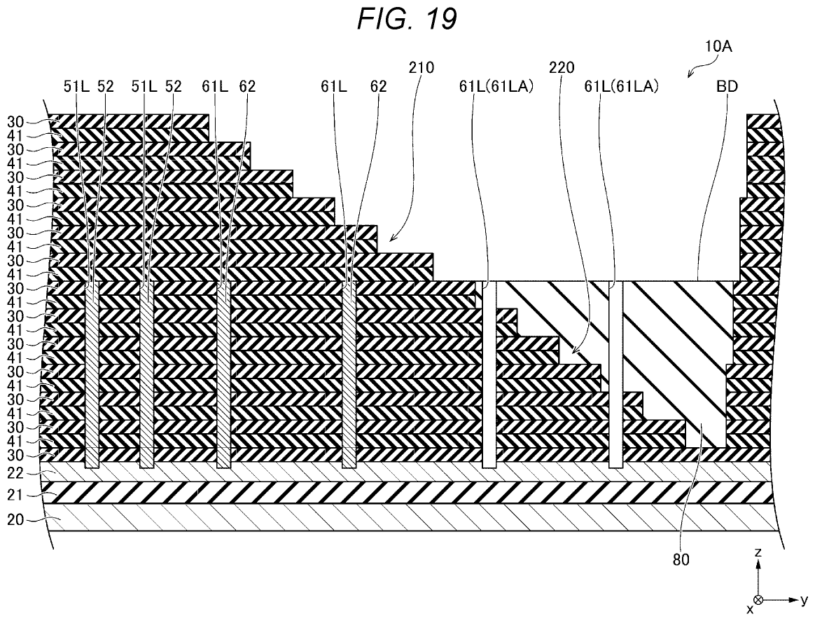

However, the nature of the carbon being removed in the ashing process may also become a disadvantage. FIG. 19 illustrates a state immediately after the upper stepped section 210 is formed in the upper step forming process when a semiconductor storage device 10A according to a comparative example being manufactured.

In this comparative example, the lower stepped section 220 is formed at a position offset from the stepped section 200 on the +y direction side. The upper stepped section 210 is formed at a position offset to the −y direction side of the lower stepped section 220. As a result, the stepped section 200 is formed as a continuous downward step structure in which end portions (terrace portions) of the conductor layers 40 connected to the contacts approach the substrate 20 with increasing distance towards the +y direction side.

In the configuration of this comparative example, once the upper stepped section 210 is formed, a part of the sacrificial material 62 embedded in the hole 61L in the lower hole forming process would be exposed at the boundary BD. From this state, the mask used for forming the upper stepped section 210 would be removed by ashing, but there is now a concern that the exposed sacrificial material 62 (which is carbon in this example) would also be removed at the same time by the ashing. In FIG. 19, the reference numeral “61LA” is given to the hole 61L in a state with the sacrificial material 62 entirely removed in this way.

After that, when the same upper hole forming process as in FIG. 12 is performed, the sacrificial material 62 intended to function as a stopper does not exist in some of the holes 61L (those designated by the reference numeral “61LA”). Therefore, there may occur a problem in that the holes 61U are dug down to a position at which it penetrates the conductor layer 22 and/or reaches the insulator layer 21. Further, there is a possibility that a part of an insulator layer 30 or a sacrificial layer 41 below the boundary BD may be improperly removed by etching. In this way, in the configuration according to the comparative example of FIG. 19, when carbon is used as the sacrificial material 62, it becomes more difficult to form the stepped section 200 into an appropriate shape.

Accordingly, in the configuration of the first embodiment illustrated in FIG. 2, a positional relationship between the upper stepped section 210 and the lower stepped section 220 is devised so as not to experience the above problem.

As illustrated in FIG. 2, in the upper stepped section 210 of the first embodiment, the conductor layers 40 are formed so as to extend longer toward one side (right side in FIG. 2) along the y direction as the layer level gets closer to the lower stepped section 220 side (lower side in FIG. 2) along the z direction, and the lower stepped section 220 is formed at a position (left side in FIG. 2) opposite to offset to one side in the y direction from the position of the upper stepped section 210 so that the −y direction side edge of the upper stepped section 210 matches with position of the +y direction side edge of the lower stepped section 220. In some examples, the edges may not match in position, and the +y direction side edge of the lower stepped section 220 may be offset from the −y direction side edge of the upper stepped section 210 in the −y direction.

The first embodiment may also be said to have a configuration in which the stair-stepped face of the upper stepped section 210 faces to the +y direction and upwards (+z direction), the stair-stepped face of the lower section 220 is offset from the upper stepped section 210 to the −y direction side, but also faces to +y direction and upwards.

As illustrated in FIG. 10, in the first embodiment, even immediately after the upper stepped section 210 is formed in the upper step forming process, all the holes 61L (formed in the lower stepped section 220) and the sacrificial material 62 filling the holes 61L remain covered by insulator layers 30 and sacrificial layers 41 on the +z direction side. That is, when the upper stepped section 210 is formed, the holes 61L and the sacrificial material 62 therein which were previously formed are not exposed at all at this point in the processing.

Therefore, even when carbon is used as the sacrificial material 62, the sacrificial material 62 will not be removed from the holes 61L by the asking performed after the processing of FIG. 10. That is, the state depicted in FIG. 19 does not occur. Accordingly, carbon may be used as the sacrificial material 62, and various advantages such as a reduction in warpage may be obtained.

In this way, in the first embodiment, by devising a positional relationship between the upper stepped section 210 and the lower stepped section 220, it is possible to form the stepped section 200 including appropriate support columns 60 even when carbon (or carbon-based material) is used as the sacrificial material 62. In particular, since the support columns 60 penetrating the plurality of conductor layers 40 are formed in both the upper stepped section 210 and the lower stepped section 220, the above effect is particularly likely to be experienced.

In the first embodiment, the bridge portion BR serves to electrically connect the plurality of conductor layers 40 provided in the upper stepped section 210 and the plurality of conductor layers 40 provided in the stacked sections 100 at both sides in the y direction. The bridge portion BR also serves to electrically connect the plurality of conductor layers 40 provided in the lower stepped section 220 and the plurality of conductor layers 40 provided in the stacked section 100 on the y direction sides. The bridge portion BR is formed so as to extend along the y direction through the region of stepped section 200 to the two stacked sections 100. With such a configuration, even in a configuration of the first embodiment in which the arrangement of each of the upper stepped section 210 and the lower stepped section 220 is changed, it still is possible to perform the electrical connection between the stepped section 200 and the stacked sections 100 as before.

In addition, the electrical connections between the plurality of conductor layers 40 provided in the stepped section 200 and the plurality of conductor layers 40 provided in the stacked sections 100 may be directly performed without use of the bridge portion BR in a portion.

The bridge portion BR electrically connects the plurality of conductor layers 40 provided in the upper stepped section 210 and the plurality of conductor layers 40 provided in the stacked section 100 at a position toward the upper stepped section 210 side along the first direction with respect to the lower stepped section 220 (i.e., a position above the lower stepped section 220). In such a configuration, the contact 70 extending toward the lower stepped section 220 may be easily formed so as to penetrate the insulator 80 while avoiding the portion where the conductor layer 40 and the insulator layer 30 for the bridge portion BR are present.

### Second Embodiment

In the following, differences from the first embodiment will be mainly described, and the description that is the same as in the first embodiment will be omitted as appropriate.

A configuration of the semiconductor storage device 10 according to the second embodiment is substantially the same as the configuration in the first embodiment. However, the second embodiment is different from the first embodiment in the method of forming the opening G (illustrated in FIG. 15 and others). In the second embodiment, apart of the opening G is formed in parallel with the formation of the upper stepped section 210 in the upper step forming process.

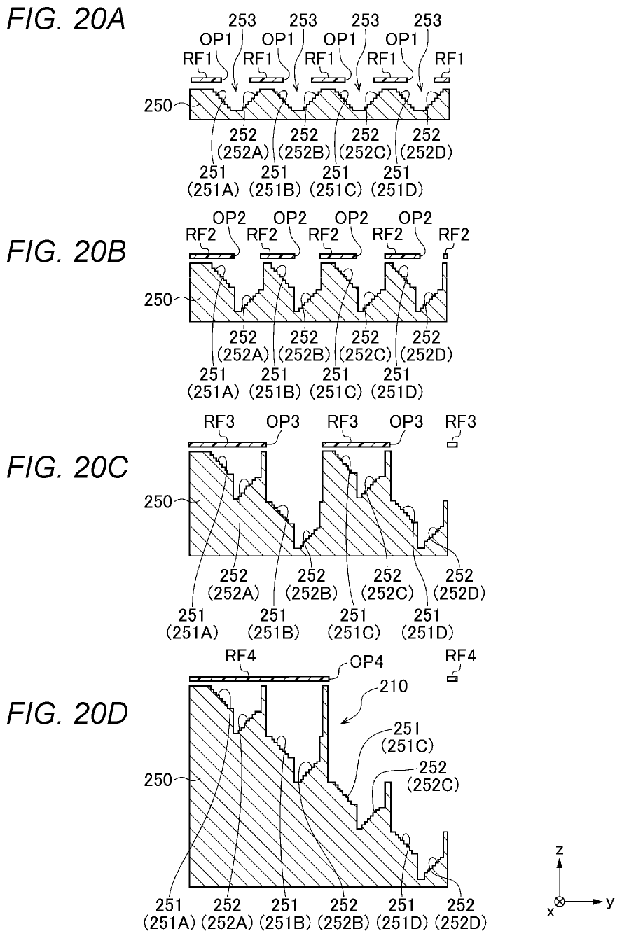

In order to illustrate the method of forming the opening G, an example of a specific method of forming the upper stepped section 210 will be described first with reference to FIGS. 20A to 20D. In FIGS. 20A to 20D, the reference numeral “250” corresponds to all of the stacked insulator layers 30 and sacrificial layers 41 on the +z direction side of the boundary BD. These stacked insulating layers 30 and sacrificial layers 41 are referred to collectively as the “stacked body 250.” That is, in FIGS. 20A to 20D, the illustration of the individual insulator layers 30 and sacrificial layers 41 within the stacked body 250 are omitted, and stacked body 250 is a single structure.

In the upper step forming process of the second embodiment, a resist film RF1 is formed as an etching mask so as to cover the surface of the stacked body 250. A plurality of openings OP1 are formed in the resist film RF1. After that, processes of anisotropic etching of the stacked body 250 and lateral trimming of the resist film RF1 are repeated. Thus, as illustrated in FIG. 20A, a stepped recess 253 is formed at a position of the stacked body 250 corresponding to each opening OP1. Note that in each of FIGS. 20A to 20D, the resist film RF1 and the stacked body 250 are depicted as being separated from each other, but are actually in close or direct contact with each other.

Each recess 253 has a stepped section 251 and a stepped section 252. The stepped section 251 is a portion of the recess 253 on the −y direction side. The stepped section 252 is a portion of the recess 253 on the +y direction side.

The respective stepped sections 251 in the figures are, from left to right, labeled as “stepped section 251A,” “stepped section 251B,” “stepped section 251C,” and “stepped section 251D”. Similarly, the respective stepped sections 252 are referred to as “stepped section 252A,” “stepped section 252B,” “stepped section 252C,” and “stepped section 252D”.

After the recesses 253 are formed, the resist film RF1 is removed from the stacked body 250.

Subsequently, as illustrated in FIG. 20B, a resist film RF2 is formed so as to cover the surface of the stacked body 250. A plurality of openings OP2 are formed in the resist film RF2. The openings OP2 are formed directly above the respective stepped sections 252. Then anisotropic etching is performed on the stacked body 250. Regions directly above the respective stepped sections 251 and above where the recesses 253 were not formed are covered by the resist film RF2. By performing anisotropic etching, the respective stepped sections 252 lowered to the −z direction side while still maintaining the stepped shape thereof. After that the downward etching of the stepped sections 252, the resist film RF2 is removed from the stacked body 250.

Next, as illustrated in FIG. 20C, a resist film RF3 is formed so as to cover the surface of the stacked body 250. A plurality of openings OP3 are formed in the resist film RF3. The openings OP3 are formed directly above the stepped section 251B and the stepped section 252B and directly above the stepped section 251D and the stepped section 252D, respectively. By performing anisotropic etching, the stepped section 251B and the stepped section 252B as well as the stepped section 251D and the stepped section 252D are lowered to the −z direction side while maintaining the shape thereof. After that, the resist film RF3 is removed from the stacked body 250.

Next, as illustrated in FIG. 20D, a resist film RF4 is formed so as to cover the surface of the stacked body 250. A plurality of openings OP4 are formed in the resist film RF4. The openings OP4 are formed over the region directly above the stepped section 251C, the stepped section 252C, the stepped section 251D, and the stepped section 252D. By performing anisotropic etching, the stepped section 251C and the stepped section 252C as well as the stepped section 251D and the stepped section 252D lowered to the −z direction side while maintaining the shape thereof. After that, the resist film RF4 is removed from the stacked body 250.

In this way, in the upper step forming process of the present embodiment, a plurality of stepped sections 251 and stepped sections 252 are first formed by repeating anisotropic etching of the stacked body 250 and lateral trimming of the resist film RF1 (FIG. 20A). After that, by partially and stepwise dropping some of the stepped sections 251 and the stepped sections 252, the upper stepped section 210 is formed such that the conductor layers 40, as a whole, get longer along the y direction as layer distance to the substrate 20 decreases (FIGS. 20B to 20D). In addition, in the upper stepped section 210 formed in this way, as illustrated in FIG. 20D, an end surface portion where a plurality of the insulator layers 30 and the sacrificial layers 41 are lowered to the −z direction side is interposed between the respective downward steps of the stepped sections 251A to 251D along the z direction. That is, as in the semiconductor storage device 10 according to the second embodiment, the stepped section 200 may have a configuration in which a part of the plurality of conductor layers 40 corresponding to the stepped sections 251 is formed to have downward steps toward one side (e.g., right side in FIGS. 20A to 20D) along the y direction. On the other hand, a part of the plurality of conductor layers 40 corresponding to the stepped sections 252 can be stepped upwards toward the one side (e.g., the right side in FIGS. 20A to 20D) along the y direction.

In the second embodiment, when stepwise dropping a stepped section 252 and the like, anisotropic etching can also be performed at the same time on a portion of the stacked body 250 that is to become the opening G. For example, in the process of FIG. 20B, an opening OP2 may also be formed in a portion of the resist film RF2 corresponding to the opening G. Similarly, for example, in the process of FIG. 20C, an opening OP3 may also be formed in a portion of the resist film RF3 corresponding to the opening G. Similarly, for example, in the process of FIG. 20D, an opening OP4 may also be formed in a portion of the resist film RF4 corresponding to the opening G. By such a method, the opening G may be formed stepwise in parallel with the formation of the upper stepped section 210.

In addition, in the above example, a stepped section 252 (252D) is dropped/lowered three times (FIG. 20B, FIG. 20C, FIG. 20D), but the number of times the dropping/lowering is actually performed may be greater than this.

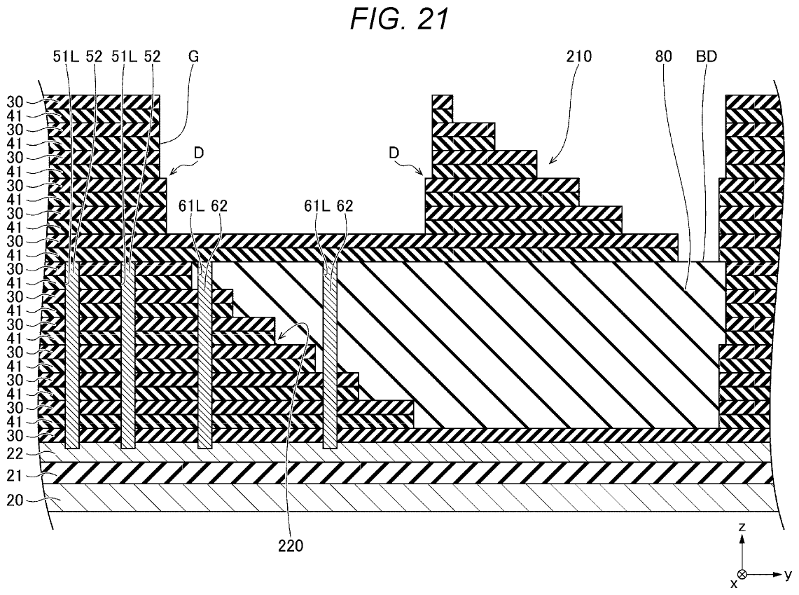

FIG. 21 schematically illustrates a state immediately after the upper stepped section 210 is formed by a method including stepwise etching of opening G. In this case, a step D is formed on the inner wall surface of the opening G due to the stepwise implementation of anisotropic etching. In FIG. 21, only one step D is formed, but the number of actually formed steps D would be larger than this when more than two etching steps are utilized.

As illustrated in FIG. 21, the opening G still does not reach the boundary BD even when the formation of the upper stepped section 210 has been completed. That is, an insulator layer 30 and a sacrificial layer 41 remain between the bottom of the opening G and the boundary BD. In addition, the actual number of layers in remaining at the bottom of opening G may be larger than that illustrated in FIG. 21. The reason why an insulator layer 30 and a sacrificial layer 41 are left at the bottom of the opening G is that anisotropic etching was not performed on a portion of the stacked body 250 corresponding to the opening G in a first process (FIG. 20A) in which the stepped recess 253 is formed.

The reason an insulator layer 30 and a sacrificial layer 41 is left in this way is that is preferable not to expose the sacrificial material 62 directly under the opening G. After reaching the state illustrated in FIG. 21, the mask used for forming the upper stepped section 210 is removed by asking. Thus, in the second embodiment, like in the first embodiment, the hole 61L and the sacrificial material 62 which were previously formed are still not exposed. Therefore, the same related effect as described for the first embodiment may be obtained.

The processes performed after reaching the state of FIG. 21 are the same as the processes described for the first embodiment. In this case, in the subsequent opening forming process, a portion (insulator layer 30 and sacrificial layer 41) between the boundary BD and the opening G which is previously formed can be removed.

In the opening forming process (FIG. 15) of the first embodiment, the plurality of insulator layers 30 and sacrificial layers 41 are stacked in a portion where the opening G is to be formed and further, a portion including the support column 60 formed of a material different from the above-mentioned portion is deeply dug by etching. Therefore, it is not easy to form the entire opening G and a processing may take time.

However, in the second embodiment, most of the opening G has already been removed before the opening forming process (similar to FIG. 15), and the inside thereof is filled with the insulator 80. Therefore, in the opening forming process of the second embodiment, the support column 60 and the insulator 80 formed of a single material are dug down by etching and thereafter, the remaining insulator layers 30, sacrificial layers 41 and the support column 60 portion at the same height as the remaining insulator layers 30, sacrificial layers 41 are further removed by etching. In the second embodiment, the portion where the insulators layer 30, the sacrificial layers 41, and the support column 60 are left in a mixed manner, (i.e., a portion where a processing by etching takes a longer time) is thinner as compared with the first embodiment. Therefore, the opening G may be more easily formed as compared with the first embodiment.

### Third Embodiment

In the following, differences in the third embodiment from the first embodiment will be mainly described, and the description of the same as in the first embodiment will be omitted as appropriate.

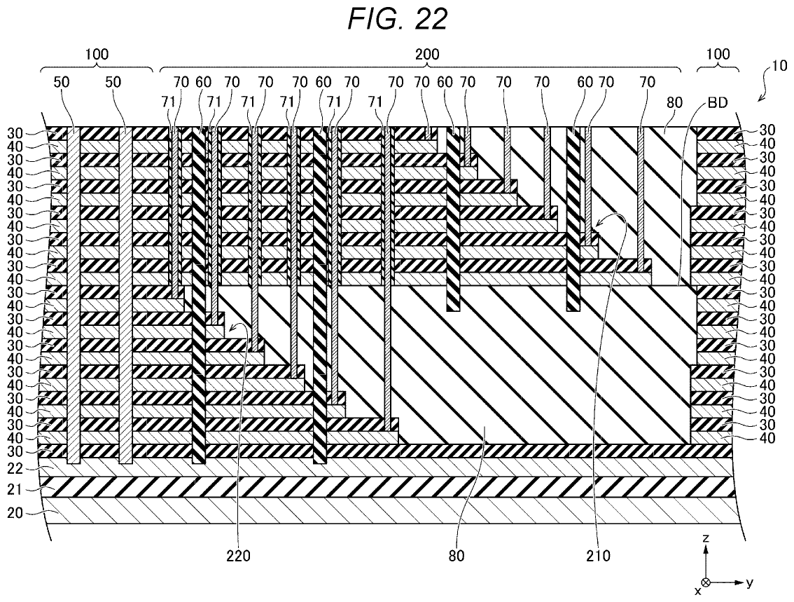

FIG. 22 schematically illustrates a configuration of the semiconductor storage device 10 according to the third embodiment from the same viewpoint and method as in FIG. 2. As illustrated in FIG. 22, in the semiconductor storage device 10 according to the third embodiment, the conductor layers 40 and the insulator layers 30 are alternately stacked in a portion directly above the lower stepped section 220 and on the +z-direction side of the boundary BD. The contact 70 connected to the lower stepped section 220 from the +z direction side is formed so as to penetrate these conductor layers 40 and the insulator layers 30. The semiconductor storage device 10 having such a configuration may be more simply manufactured by omitting the opening G forming process described above.

An insulating film 71 is formed so as to cover the outside surface of the contact 70 in the portion directly above the lower stepped section 220 and on the +z direction side of the boundary BD. The insulating film 71 serves to prevent conduction between the contact 70 and each conductor layer 40 in the upper stepped section 210. In some examples, the entire outside surface of the contact 70 may be covered by the insulating film 71 even in a portion on the −z direction side of the boundary BD.

Similarly, when forming the opening G by using the method described for the second embodiment, as illustrated in FIG. 21, the semiconductor storage device 10 may be manufactured without undergoing the opening forming process to remove any remaining the insulators layer 30 and sacrificial layers 41 between the bottom of opening G and the boundary BD. In such a case, there may be a plurality of insulator layers 30 and conductor layers 40 formed between the bottom of opening G and the lower stepped section 220. However, even with such a configuration, a contact 70 connected to the lower stepped section 220 from the +z direction side may be formed so as to penetrate these conductor layers 40 and the insulator layers 30 and to have, similarly to FIG. 22, its outside surface covered by insulating film 71.

Also in this case, the semiconductor storage device 10 may be more simply manufactured since the complete opening forming process is not required. Furthermore, with such a configuration, the portion (length) of the contact 70 along which conductor layers 40 are close by with the insulating film 71 interposed therebetween may be reduced as compared with the configuration of FIG. 22, so that an improvement in the durability of the semiconductor storage device 10 may be expected.

### Fourth Embodiment

In the following, differences in a fourth embodiment from the first embodiment will be mainly described, and the description the same as in the first embodiment will be omitted as appropriate.

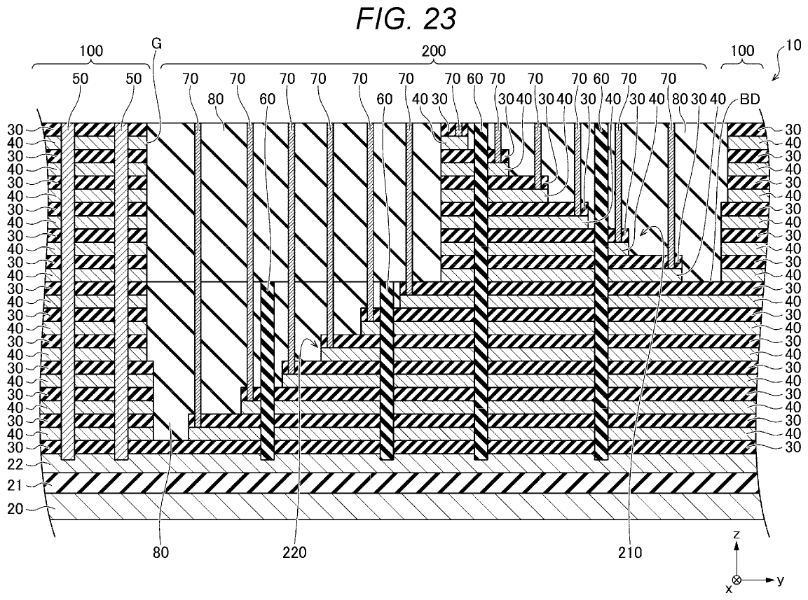

FIG. 23 schematically illustrates a configuration of the semiconductor storage device 10 according to the fourth embodiment from the same viewpoint and method as in FIG. 2. As illustrated in FIG. 23, the semiconductor storage device 10 according to the fourth embodiment has a shape in which the lower stepped section 220 is inverted (as compared to the first embodiment (FIG. 2)) so that the steps of the lower stepped section 220 face in the opposite direction of the upper stepped section 210. That is, the conductor layers 40 in the lower stepped section 220 are stepped upward toward the one side (e.g., right side in FIG. 23) along the y direction, and the conductor layers 40 in the upper stepped section 210 are stepped downward toward the one side along the y direction.

In the fourth embodiment, each conductor layer 40 stacked in the lower stepped section 220 is electrically connected to a respective one of the conductor layers 40 stacked in the stacked section 100 on the −y direction side which is located at the same height position (z coordinate) via the bridge portion BR similar to that illustrated in FIG. 4. Each conductor layer 40 in the lower stepped section 220 is directly connected to a respective one of the conductor layers 40 in the stacked section 100 on the +y direction side, which is located at the same height position (z coordinate).

The semiconductor storage device 10 having such a configuration may be manufactured by the same method as the method described for the first embodiment. The opening G in the fourth embodiment may be formed by the same opening forming process as that described for the first embodiment, or may be formed by the same method as that described for the second embodiment. Also in the fourth embodiment, the same effects as described for the first embodiment, specifically, the effect in that the sacrificial material 62 is not removed when the upper stepped section 210 is formed may be achieved even when carbon is used as the sacrificial material 62.

### Fifth Embodiment

In the following, differences in a fifth embodiment from the fourth embodiment will be mainly described, and the description of the same as for the fourth embodiment will be omitted as appropriate.

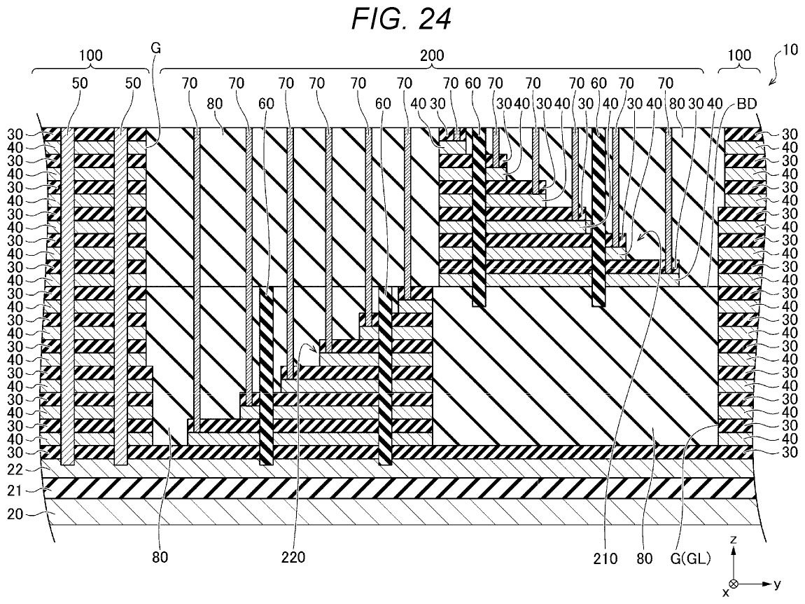

FIG. 24 schematically illustrates a configuration of the semiconductor storage device 10 according to the fifth embodiment from the same viewpoint and method as in FIG. 23. In the fifth embodiment, the opening G is also formed in a portion directly below the upper stepped section 210 on the −z direction side of the boundary BD. The opening G formed in this portion is also referred to as “opening GL.”

In the opening GL, the insulator layer 30 and the conductor layer 40 are not present, and the entire interior of opening GL is filled with the insulator 80. For example, the opening GL may be formed by using the same method as the opening forming process (FIG. 15) in a step after the lower hole forming process is completed but before the upper stacking process is performed.

A bridge portion BR similar to that illustrated in FIG. 4 is formed in a portion on an x direction side of the opening GL. This bridge portion BR electrically connects each conductor layer 40 stacked in the lower stepped section 220 and a respective one (same z coordinate) of the conductor layers 40 stacked in the stacked section 100 on the +y direction side

In the semiconductor storage device 10 having such a configuration, the conductor layers 40 and the support columns 60 are not formed in a region on the −z direction side of the upper stepped section 210.

In the fifth embodiment, in addition to the same effects as in the fourth embodiment, the same effects as in the first embodiment in that a connection failure is prevented between a contact 70 and the conductor layer 40 of the upper stepped section 210 located at close to the boundary BD may also be achieved.

### Sixth Embodiment

In the following, differences in the sixth embodiment from the first embodiment will be mainly described, and the description of the same as in the first embodiment will be omitted as appropriate.

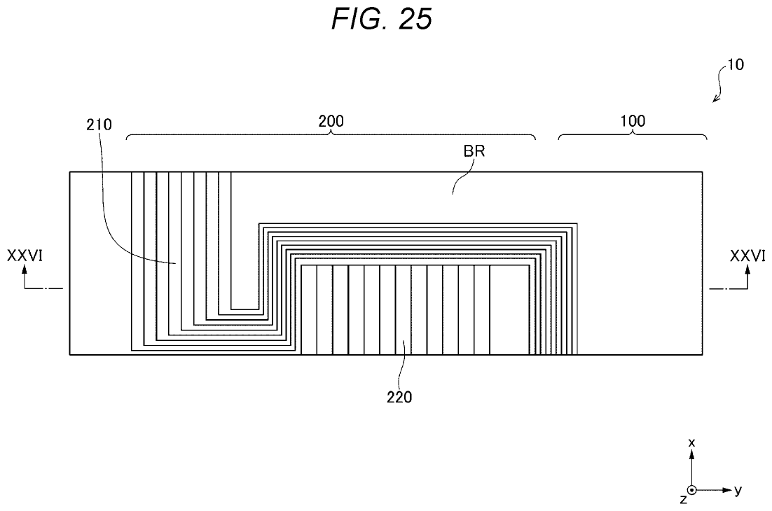

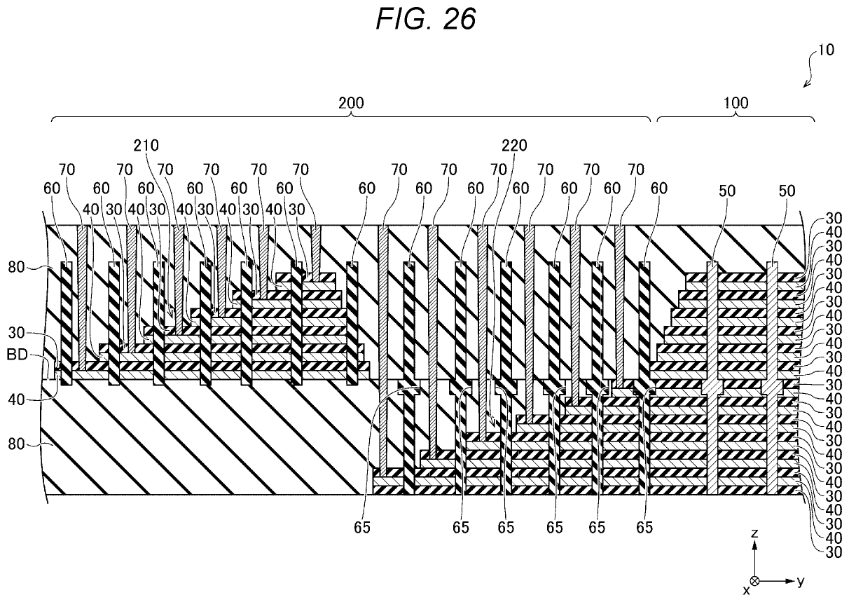

FIG. 25 is a diagram schematically depicting a configuration of the semiconductor storage device 10 according to the sixth embodiment when viewed from the z direction side. FIG. 26 is a diagram illustrating the XXVI-XXVI cross section of FIG. 25. In FIG. 25, the illustration omits specific depiction of the insulator 80 (which fills the periphery of the stepped section 200) in order to more clearly illustrate the configuration of the stepped section 200. Furthermore, the specific illustration of the support columns 60 and the contacts 70 is also omitted.

In the sixth embodiment, the stacked sections 100 are not located at positions at both sides of the stepped section 200 along the y direction, but rather just a single stacked section 100 (located a position on the +y-direction side of the stepped section 200) is provided. As illustrated in FIG. 26, the upper stepped section 210 is located at a position on the −y direction side of the lower stepped section 220. That is, the upper stepped section 210 is located at a position opposite to the stacked section 100 with the lower stepped section 220 interposed therebetween.

In the sixth embodiment, each conductor layer 40 in the lower stepped section 220 is directly connected to the respective one of the conductor layers 40 [symbol] in the stacked section 100 which is located at the same height position (z coordinate). Each conductor layer 40 in the upper stepped section 210 is connected to the respective one of the conductor layers 40 in the stacked section 100 which is located at the same height position (z coordinate) via a conductor layer 40 routed along the +x direction side of the lower stepped section 220. In this configuration, it may be said that the bridge portion BR extending in the y direction on the +x-direction side of the lower stepped section 220 electrically connects each conductor layer 40 of the upper stepped section 210 and a corresponding one of the conductor layers 40 in the stacked section 100.

In the upper stepped section 210, the lower conductor layers 40 in the stack are formed so as to extend more to the left side of FIG. 26. The lower stepped section 220 is formed at a position offset to one side in the y direction from the upper stepped section 210. Also in the sixth embodiment, the same effects as described in the first embodiment can be obtained.

In addition, in each of the above embodiments, the upper stepped section 210 and the lower stepped section 220 are illustrated with relation to a case where the terrace portions where the conductor layers 40 and the contact 70 are connected are arranged in a row along the y direction, but in the semiconductor storage device 10 according to each embodiment, the stepped section 200 may have a configuration in which two or more rows of terrace portions are arranged along the y direction and steps in multiple layers corresponding to the conductor layer 40 can be formed between the terrace surfaces adjacent to each other in the y direction.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a plurality of conductor layers stacked along a first direction, the plurality of conductor layers comprising:
a first stacked section,
a stepped section next to the first stacked section in a second direction orthogonal to the first direction, the plurality of conductor layers in the stepped section having a stepped shape in which the conductor layers arranged in the first direction have end portions that do not overlap in the first direction, wherein
the stepped section includes a lower stepped section and an upper stepped section located at a position different from the lower stepped section along the first direction,
in the upper stepped section, the conductor layers closer to the lower stepped section side along the first direction extend longer toward one side along the second direction, and
the lower stepped section is located at a position toward an opposite side to the one side along the second direction with respect to the upper stepped section.

2. The semiconductor storage device according to claim 1, wherein each of the upper stepped section and the lower stepped section has at least one support column penetrating corresponding portions of the plurality of conductor layers.

3. The semiconductor storage device according to claim 2, wherein the at least one support column in the upper stepped section does not penetrate any portion of the plurality of conductor layers extending along the second direction from the lower stepped section.

4. The semiconductor storage device according to claim 2, wherein the at least one support column in the lower stepped section penetrates portions of the plurality of conductive layers extending along the second direction from the upper stepped section.

5. The semiconductor storage device according to claim 4, further comprising:
a plurality of contacts connected respectively to the plurality of conductor layers provided in the lower stepped section, wherein
the plurality of contacts penetrate portions of the plurality of conductive layers extending along the second direction from the upper stepped section, but are not electrically connected to the plurality of conductor layers extending along the second direction from the upper stepped section.

6. The semiconductor storage device according to claim 1, wherein
the plurality of conductor layers further comprises a first bridge portion that electrically connects a portion of the conductor layers in the upper stepped section and a portion of the conductor layers in the first stacked section, and
the first bridge portion extends in the second direction at the position toward the opposite side along the second direction with respect to the upper stepped section.

7. The semiconductor storage device according to claim 6, wherein
the plurality of conductor layers further comprises a second stacked section spaced from the first stacked section in the second direction,
the stepped section is between the first stacked section and the second stacked section in the second direction, and
the first bridge portion extends in the second direction between the first stacked section and the second stacked section to further electrically connect the portion of the conductor layers in the upper stepped section and a portion of the conductor layers in the second stacked section.

8. The semiconductor storage device according to claim 1, wherein the plurality of conductor layers are not in a region that is below the upper stepped section in the first direction and adjacent to the lower stepped section in the second direction.

9. The semiconductor storage device according to claim 1, wherein, in the lower stepped section, the conductor layers farther away from the upper stepped section side along the first direction extend longer toward the one side along the second direction.

10. The semiconductor storage device according to claim 1, wherein the conductor layers in the lower stepped section are stepped upward toward the one side along the second direction, and the conductor layers in the upper stepped section are stepped downward toward the one side along the second direction.

11. The semiconductor storage device according to claim 10, wherein
the plurality of conductor layers further comprises a second bridge portion that electrically connects a portion of the conductor layers in the lower stepped section and a portion of the conductor layers in the first stacked section, and
the second bridge portion extends in the second direction at the position toward the opposite side along the second direction with respect to the upper stepped section.

12. A semiconductor storage device, comprising:
a plurality of conductor layers stacked along a first direction, the plurality of conductor layers comprising:
a first stacked section, and
a stepped section next to the first stacked section in a second direction orthogonal to the first direction, the plurality of conductor layers in the stepped section have a stepped shape in which the conductor layers arranged in the first direction have end portions that do not overlap in the first direction, wherein
the stepped section includes a lower stepped section and an upper stepped section located at a position different from the lower stepped section along the first direction,
in the upper stepped section, the conductor layers closer to the lower stepped section side along the first direction extend longer toward one side along the second direction, and
the conductor layers are not in a region toward the lower stepped section side along the first direction with respect to the upper stepped section.

13. The semiconductor storage device according to claim 12, wherein each of the upper stepped section and the lower stepped section has at least one support column penetrating corresponding portions of the plurality of conductor layers.

14. The semiconductor storage device according to claim 13, wherein the at least one support column in the lower stepped section penetrates portions of the plurality of conductive layers extending along the second direction from the upper stepped section.

15. The semiconductor storage device according to claim 14, further comprising:
a plurality of contacts connected respectively to the plurality of conductor layers provided in the lower stepped section, wherein
the plurality of contacts penetrate portions of the plurality of conductive layers extending along the second direction from the upper stepped section, but are not electrically connected to the plurality of conductor layers extending along the second direction from the upper stepped section.

16. The semiconductor storage device according to claim 12, wherein
the plurality of conductor layers further comprises a first bridge portion that electrically connects a portion of the conductor layers in the upper stepped section and a portion of the conductor layers in the first stacked section, and
the first bridge portion extends in the second direction at a position toward an opposite side to the one side along the second direction with respect to the upper stepped section.

17. The semiconductor storage device according to claim 16, wherein
the plurality of conductor layers further comprises a second stacked section spaced from the first stacked section in the second direction,
the stepped section is between the first stacked section and the second stacked section in the second direction, and
the first bridge portion extends in the second direction between the first stacked section and the second stacked section to further electrically connect the portion of the conductor layers in the upper stepped section and a portion of the conductor layers in the second stacked section.

18. The semiconductor storage device according to claim 12, wherein
the lower stepped section is located at a position toward an opposite side to the one side along the second direction with respect to the upper stepped section, and
in the lower stepped section, the conductor layers farther away from to the upper stepped section side along the first direction extend longer toward the one side along the second direction.

19. The semiconductor storage device according to claim 12, wherein
the plurality of conductor layers further comprises a second stacked section spaced from the first stacked section in the second direction,
the stepped section is between the first stacked section and the second stacked section in the second direction, the conductor layers in the lower stepped section are stepped upward toward the second stacked section, and
the conductor layers in the upper stepped section are stepped downward toward the second stacked section.

20. The semiconductor storage device according to claim 19, wherein
the plurality of conductor layers further comprises a second bridge portion that electrically connects between a portion of the conductor layers in the lower stepped section and a portion of the conductor layers in the first stacked section and between the portion of the conductor layers in the lower stepped section and a portion of the conductor layers in the second stacked section, and
the second bridge portion extends in the second direction between the first stacked section and the second stacked section.
